(19) United States
(12) Patent Application Publication
(10) Pub. No.: US 2026/0081577 A1
(43) Pub. Date: Mar. 19, 2026

(54) EMBEDDED SILICON DIOXIDE IN ELECTRODE TO REDUCE TEMPERATURE COEFFICIENT OF FREQUENCY IN BULK ACOUSTIC WAVE RESONATOR

(71) Applicant: SKYWORKS GLOBAL PTE, LTD., Singapore (SG)

(72) Inventors: Kwang Jae Shin, Yongin-si (KR); Taecheol Shon, Hwaseong-si (KR); Youngjun Kim, Hwaseong-si (KR)

(21) Appl. No.: 19/330,023

(22) Filed: Sep. 16, 2025

Related U.S. Application Data
(60) Provisional application No. 63/696,469, filed on Sep. 19, 2024.

(51) Int. Cl. H03H 9/02; H03H 9/17; H03H 9/56

(52) U.S. Cl. CPC H03H 9/02102; H03H 9/172; H03H 9/568

(57) ABSTRACT

Aspects and embodiments disclosed herein include a film bulk acoustic wave resonator comprising a layer of piezoelectric material disposed between a top electrode and a bottom electrode and a temperature compensating material disposed within one of the top electrode or bottom electrode.

### CROSS-REFERENCE TO RELATED APPLICATIONS

This application claims priority under 35 U.S.C. § 119(e) to U.S. Provisional Patent Application Ser. No. 63/696,469, titled “EMBEDDED SILICON DIOXIDE IN ELECTRODE TO REDUCE TEMPERATURE COEFFICIENT OF FREQUENCY IN BULK ACOUSTIC WAVE RESONATOR,” filed Sep. 19, 2024, the entire content of which is incorporated herein by reference for all purposes.

### TECHNICAL FIELD

Embodiments of this disclosure relate to bulk acoustic wave resonators and to acoustic wave filters including same.

### DESCRIPTION OF RELATED TECHNOLOGY

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a film bulk acoustic wave resonator. The film bulk acoustic wave resonator comprises a layer of piezoelectric material disposed between a top electrode and a bottom electrode, and a temperature compensating material disposed within one of the top electrode or the bottom electrode.

In some embodiments, the temperature compensating material has a positive temperature coefficient of frequency.

In some embodiments, the temperature compensating material includes one of silicon dioxide, doped silicon dioxide, or a metal having a positive temperature coefficient of frequency.

In some embodiments, the temperature compensating material is present in the one of the top electrode or the bottom electrode as an unpatterned layer of temperature compensating material.

In some embodiments, the layer of temperature compensating material divides the top electrode into an upper portion and a lower portion.

In some embodiments, the upper portion is thicker than the lower portion.

In some embodiments, the lower portion is thicker than the layer of temperature compensating material.

In some embodiments, the upper portion is thinner than the lower portion.

In some embodiments, the temperature compensating material is disposed within the bottom electrode.

In some embodiments, the temperature compensating material is disposed within the top electrode and the bottom electrode.

In some embodiments, the temperature compensating material is present in the one of the top electrode or the bottom electrode as a patterned layer of material.

In some embodiments, the temperature compensating material is present in the one of the top electrode or the bottom electrode as a one of plurality of strips, a plurality of rectangles, a plurality of ovals, or as a grid of the temperature compensating material.

In some embodiments, the plurality of strips of temperature compensating material has a duty factor of at least 0.2.

In some embodiments, the plurality of strips of temperature compensating material has a duty factor of at least 0.5.

In some embodiments, the plurality of strips are coplanar.

In some embodiments, the temperature compensating material is disposed within the top electrode.

In some embodiments, the temperature compensating material is disposed within the bottom electrode.

In some embodiments, the temperature compensating material is disposed within the top electrode and the bottom electrode.

In some embodiments, the temperature compensating material is disposed within at least one of the top electrode and the bottom electrode.

In some embodiments, the film bulk acoustic wave resonator is included in a radio frequency filter.

In some embodiments, the radio frequency filter is configured as a ladder filter.

In some embodiments, the radio frequency filter is included in a radio frequency module.

In some embodiments, the radio frequency module is included in a radio frequency device.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of film bulk acoustic wave resonator including a layer of temperature compensation material disposed between an upper electrode and a layer of piezoelectric material;

FIG. 3A is a cross-sectional view of an example of film bulk acoustic wave resonator including a continuous layer of temperature compensation material disposed within the upper electrode;

FIG. 3B is a cross-sectional view of an example of film bulk acoustic wave resonator including a patterned layer of temperature compensation material disposed within the upper electrode;

FIG. 3C illustrates cross-sectional diagrams of portions of material layer stacks of examples of BAW resonators including continuous and patterned layers of temperature compensation material disposed within the bottom electrode;

FIG. 4 is a table of thicknesses of material layers in examples of BAW resonators including temperature compensation layers and selected performance characteristics;

FIG. 5 illustrates the results of testing of quality factor and electromechanical coupling coefficient of BAW resonators fabricated with material layer stacks as described in FIG. 4;

FIG. 6 illustrates the results of testing of magnitude vs. frequency of the H3 harmonic in BAW resonators fabricated with material layer stacks as described in FIG. 4;

FIG. 7 illustrates how temperature compensation material may be included as either a continuous layer of a plurality of strips in an electrode of a BAW resonator;

FIG. 8 illustrates the effect of duty factor of strips of temperature compensation material in an electrode of a BAW resonator on resonant frequency of the resonator;

FIG. 9 illustrates a simplified schematic diagram of a ladder filter that may be formed from resonators as disclosed herein;

FIG. 10 illustrates an embodiment of an electronics module;

FIG. 11 illustrates an example of a front-end module which may be used in an electronic device; and

FIG. 12 illustrates an example of an electronic device.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined in part by a thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

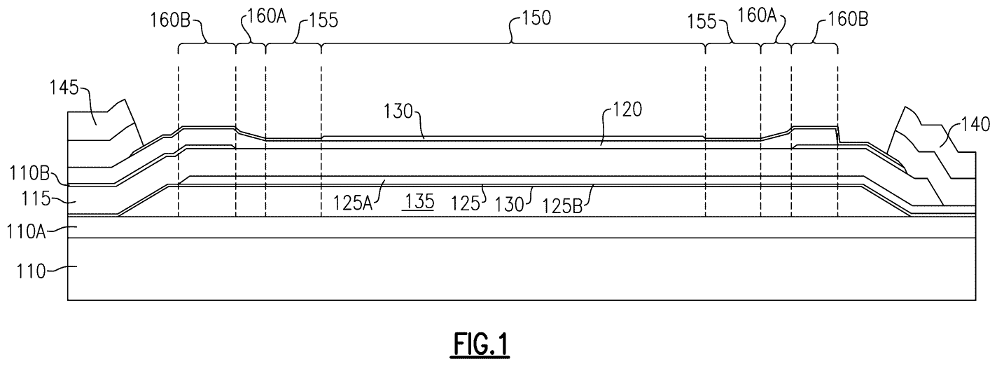

FIG. 1 is cross-sectional view of an example of a film bulk acoustic wave resonator. The film bulk acoustic wave resonator is disposed on a substrate 110, for example, a silicon substrate that may include a dielectric surface layer 110A of, for example, silicon dioxide. The film bulk acoustic wave resonator includes a layer or film of piezoelectric material 115, for example, aluminum nitride (AlN) or scandium-doped aluminum nitride (AlₓSc₁₋ₓN, referred to herein without subscripts as AlScN). A top electrode 120 (often abbreviated MTE for Metal Top Electrode) is disposed on top of a portion of the layer or film of piezoelectric material 115 and a bottom electrode 125 (often abbreviated MBE for Metal Bottom Electrode) is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. An air cavity 135 is defined between the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 (also referred to as a central active region) including a main active domain in the layer or film of piezoelectric material 115 in which a main acoustic wave is excited during operation. The central region may have a width of, for example, between about 20 μm and about 100 μm. A recessed frame region or regions 155 may be disposed around, bound, and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150, or in other embodiments a thinner portion of the top electrode 120 than the portion of the top electrode in the central region 150. The layer of dielectric material 130 in the recessed frame region(s) 155 may be from about 10 nm to about 100 nm thinner than the layer of dielectric material 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the layer of dielectric material 130 in the central region 150 may be about 200 nm to about 300 nm and the thickness of the layer of dielectric material 130 in the recessed frame region(s) 155 may be about 100 nm. The layer of dielectric material 130 in the recessed frame region(s) 155 is typically etched during manufacturing to achieve a desired difference in acoustic velocity between the central region 150 and the recessed frame region(s) 155. Accordingly, the layer of dielectric material 130 initially deposited in both the central region 150 and recessed frame region(s) 155 is deposited with a sufficient thickness that allows for etching of sufficient dielectric material 130 in the recessed frame region(s) 155 to achieve a desired difference in thickness of the layer of dielectric material 130 in the central region 150 and recessed frame region(s) 155 to achieve a desired acoustic velocity difference between these regions.

A metal raised frame region or regions 160A and an oxide raised frame region or regions 160B (collectively, raised frame region or regions 160) may be defined around the central region 150 on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The oxide raised frame region(s) 160B may additionally include a layer of silicon dioxide 110B between the top electrode and the layer or film of piezoelectric material 115. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

It should be appreciated that the BAW resonators and portions of same illustrated in the figures are illustrated in a highly simplified form. The relative dimensions of the different features are not shown to scale. Further, typical BAW resonators may include additional features or layers not illustrated.

Important operating parameters for a BAW resonator include temperature coefficient of frequency (TCF), which may be considered the amount by which the operating frequency (e.g., resonance and/or anti-resonance frequency) of the resonator changes with changes in temperature, electromechanical coupling coefficient (kₜ²), which is related to the difference in frequency between the resonance and anti-resonance frequencies of the resonator, and quality factor Q, which may be considered as the amount of input energy that is stored or converted to desired acoustic waves within the resonator rather than lost due to, for example, electrical or acoustic wave energy leakage from the active region of the resonator.

One method by which one may improve the TCF of a BAW resonator to decrease the amount by which the operating frequency of the resonator changes with changes in temperature is to place a material exhibiting an opposite change in acoustic velocity with change in temperature than that of the piezoelectric material layer of the BAW resonator proximate the piezoelectric material layer. Most piezoelectric materials commonly used for the piezoelectric material layer of a BAW resonator, for example, aluminum nitride or scandium-doped aluminum nitride exhibit a decrease in acoustic velocity with increasing temperature. This leads to a decrease in operating frequency of the BAW resonator with increasing temperature.

Piezoelectric materials such as aluminum nitride or scandium-doped aluminum nitride may thus be considered “negative TCF” materials. Other materials, for example, silicon dioxide exhibit an increase in acoustic velocity with increasing temperature. Materials such as silicon dioxide may thus be considered “positive TCF” materials or “temperature compensating” material. Other temperature compensating materials may include silicon dioxide doped with one or more of fluorine (F), nitrogen (N), boron (B), phosphorus (P), or carbon (C) or a positive TCF metal such as Invar® alloy, Elinvar alloy, or Co₂₅Ni₂₅(Hf, Ti, Zr)₅₀. Other positive TCF materials known in the art may additionally or alternatively be utilized.

Accordingly, one method of reducing the effect of temperature on the operating frequency of a BAW resonator is to place a layer of silicon dioxide or other temperature compensating material on the upper and/or lower surface of the layer of piezoelectric material.

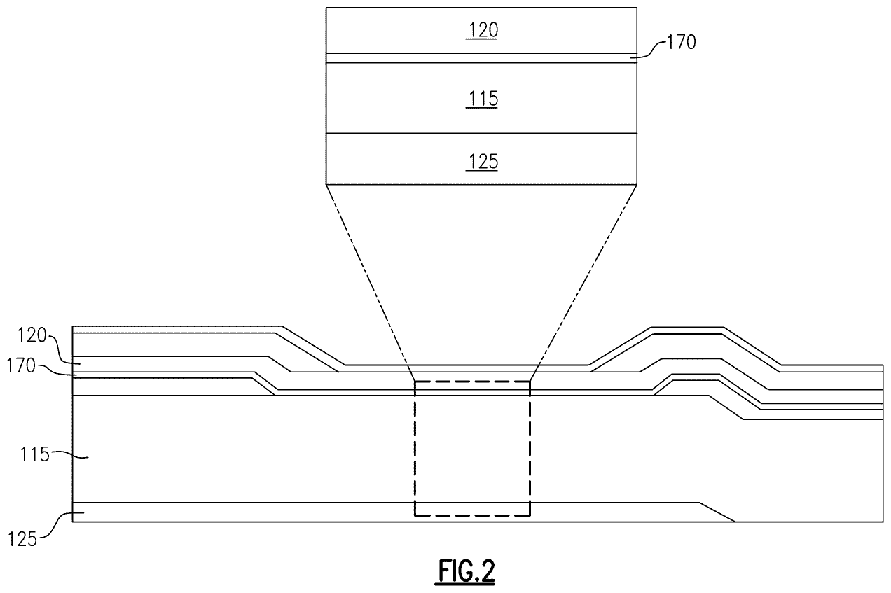

An example of this is shown in FIG. 2 where a layer of temperature compensating material 170 (for example, silicon dioxide) is disposed between the top electrode 120 and the layer of piezoelectric material 115 in one example of a BAW resonator. It is to be understood that a layer of temperature compensating material 170 may additionally or alternatively be disposed between the bottom electrode 125 and the layer of piezoelectric material 115.

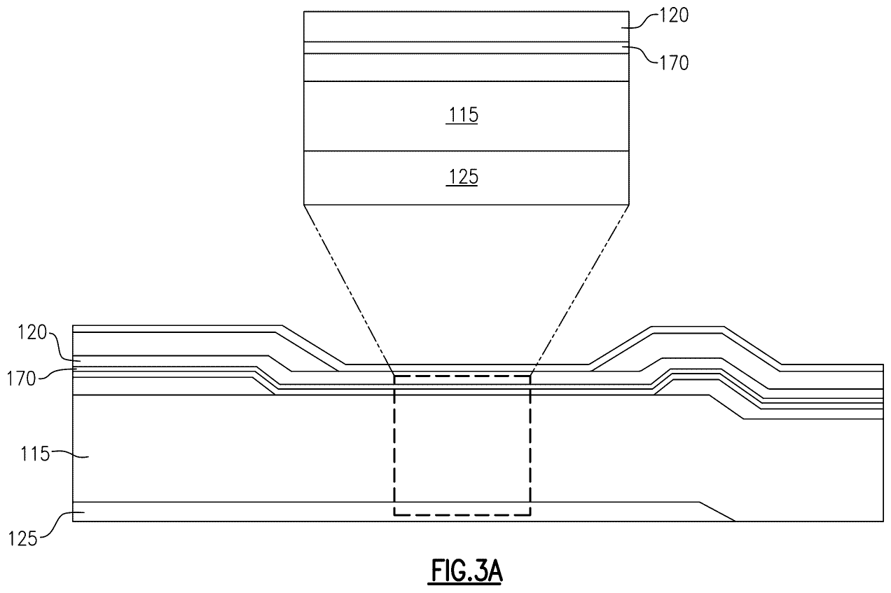

The temperature compensating method and structure illustrated in FIG. 2 may not be ideal. Placing the layer of temperature compensating material 170 between an electrode (e.g., the top electrode 120 as illustrated in FIG. 2) and the layer of piezoelectric material 115 puts the layer of temperature compensating material 170 within the electric field between the electrode and the layer of piezoelectric material 115. This may create adverse effects such as degradation of quality factor Q and/or electromechanical coupling coefficient kₜ² of the resonator. Further, strain in the layer of piezoelectric material 115 caused by deposition of the layer of temperature compensating material 170 may increase nonlinear operating behavior of the resonator such as an increase in H2 or H3 harmonics or other spurious signals due to intermodulation distortions. One method by which these disadvantages may be mitigated is by placing the layer of temperature compensating material 170 within the electrode (top electrode 120 and/or bottom electrode 125) itself. An example of this is shown in FIG. 3A in which an unpatterned layer of temperature compensating material 170 is disposed within the top electrode 120 of an example of a BAW resonator and in FIG. 3B in which a patterned layer of temperature compensating material 170 is disposed within the top electrode 120 of another example of a BAW resonator.

The top electrode 120 is partially divided into an upper portion and a lower portion by the layer of temperature compensating material 170. FIG. 3C illustrates examples in which the unpatterned or patterned layers of temperature compensating material 170 are formed within the bottom electrode 125. The embodiments of FIGS. 3A-3C may be combined and the temperature compensating material 170 may be disposed within both the top electrode 120 and the bottom electrode 125 and may be patterned or not.

It has been observed that the closer the layer of temperature compensating material 170 is to the layer of piezoelectric material 115, the more effective it is in reducing the magnitude of the TCF of the resonator. Thinner layers of temperature compensating material 170 may thus be utilized to achieve equivalent reduction in the magnitude of the TCF of the resonator the lower it is placed in the top electrode 120 (or the higher it is placed in the bottom electrode 125).

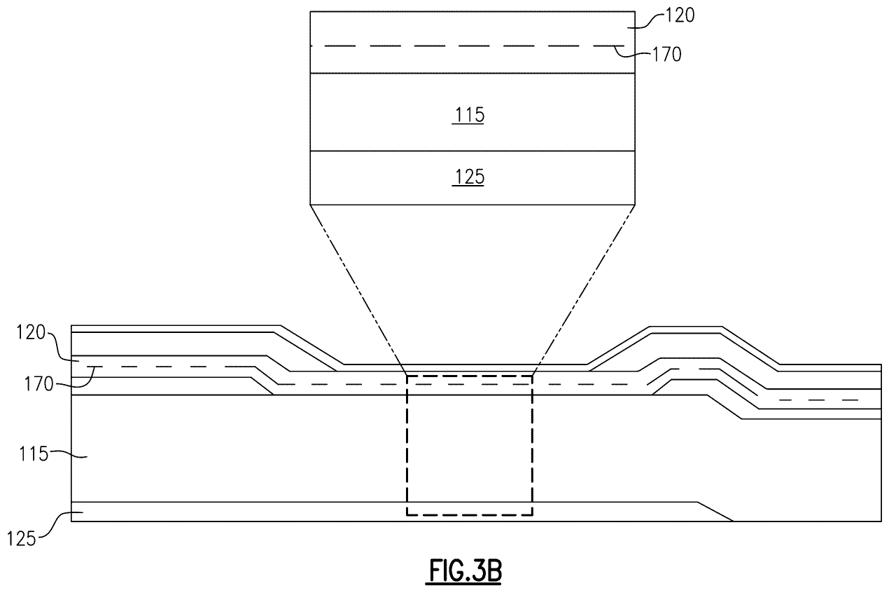

Simulations were performed to determine the thickness of the layer of temperature compensating material 170 as a function of position within a top electrode 120 with a total thickness of about 250 nm that would result in a TCF for a BAW resonator as disclosed herein of −14.3 ppm/° C. Results of these simulations and the different material layer thicknesses within the central active region of the resonator are shown in the table of FIG. 4. In this table “MTE2” is the portion of the top electrode 120 above the layer of temperature compensating material 170 shown in FIG. 1, “TC” is the layer of temperature compensating material 170, and “MTE1” is the portion of the top electrode 120 below the layer of temperature compensating material 170. The fractions in the top of each column ( (¼), ( 2/4), (¾), etc.) represent the thickness of the portion of the top electrode 120 above the layer of temperature compensating material 170 over the thickness of the portion of the top electrode 120 below the layer of temperature compensating material 170. The first column “POR(TCBAW)” in FIG. 4 refers to a BAW resonator with the layer of temperature compensating material 170 between the top electrode 120 and the layer of piezoelectric material 115, such as is illustrated in FIG. 2.

As can be observed from the table in FIG. 4, the thickness of the layer of temperature compensating material TC was able to be reduced from about 178 nm to about 49 nm as its position in the upper electrode dropped from the “(¼)” position to the “( 4/1)” position. As also can be observed from this table, the electromechanical coupling coefficient kₜ² was higher for all examples in which the layer of temperature compensating material TC was embedded in the upper electrode as compared to the POR(TCBAW) example in which the TC layer was disposed between the upper electrode and the layer of piezoelectric material. Furthermore, kₜ² improved from about 7.3% to about 7.6% as the position of the TC layer in the upper electrode dropped from the “(¼)” position to the “( 4/1)” position. Additionally, the size of the resonator was able to be reduced from about 10,230 μm² for the POR(TCBAW) example to between about 8,500 μm² and about 8,600 μm² for each example in which the layer of temperature compensating material TC was embedded in the upper electrode due to the effect of the layer of temperature compensating material TC on reducing the capacitance of the resonator.

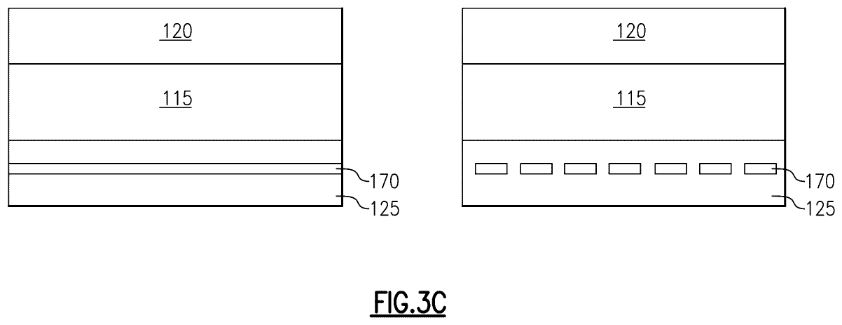

Testing was performed on BAW resonators formed with the layer thicknesses indicated in the table of FIG. 4 to determine the effect of quality factor at the resonance (Qₛ) and anti-resonance (Qₚ) frequencies of the resonators. This test data is presented in FIG. 5 in which the fractions in the top row indicate what resonator structure as illustrated in the table of FIG. 4 produced the data in the respective columns. Note that the “(¼)” structure was not tested. From the data in FIG. 5 it can be seen that there was a moderate decrease in Qₛ from the POR(TCBAW) example in each of the examples in which the TC layer was embedded in the upper electrode with Qₛ decreasing with TC layer depth in the upper electrode. The values for Qₚ were largely unaffected by inclusion of the TC layer in the upper electrode. There was, however, a significant increase in kₜ² for all examples in which the TC layer was embedded in the upper electrode as compared to the POR(TCBAW) example.

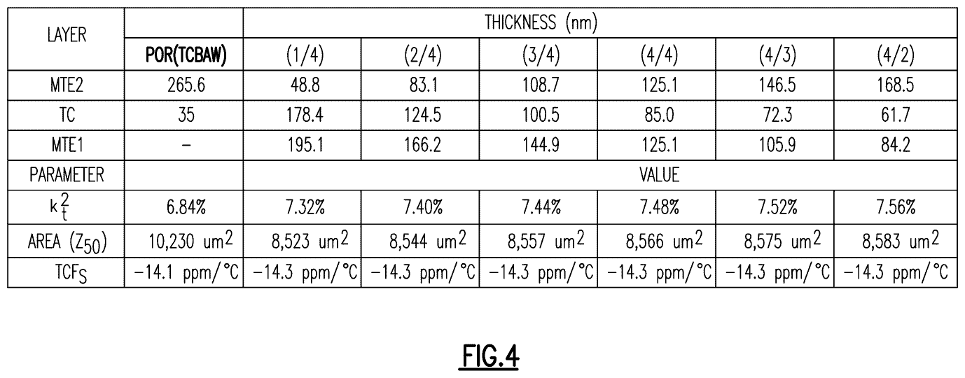

Testing was also performed to determine how the magnitude and frequency at which spurious higher order harmonics signals were observed in resonators formed with the layer thicknesses indicated in the table of FIG. 4. FIG. 6 presents results of this testing of the amplitude and location of the H3 harmonic for resonators with areas of 2,500 μm², 5,000 μm², 10,000 μm², and 25,000 μm² and the layer structures shown in FIG. 4. The general trend was a decrease in magnitude of the H3 harmonic with decrease in height of the TC layer within the upper electrode, with this effect being more pronounced for the resonators with the smaller areas.

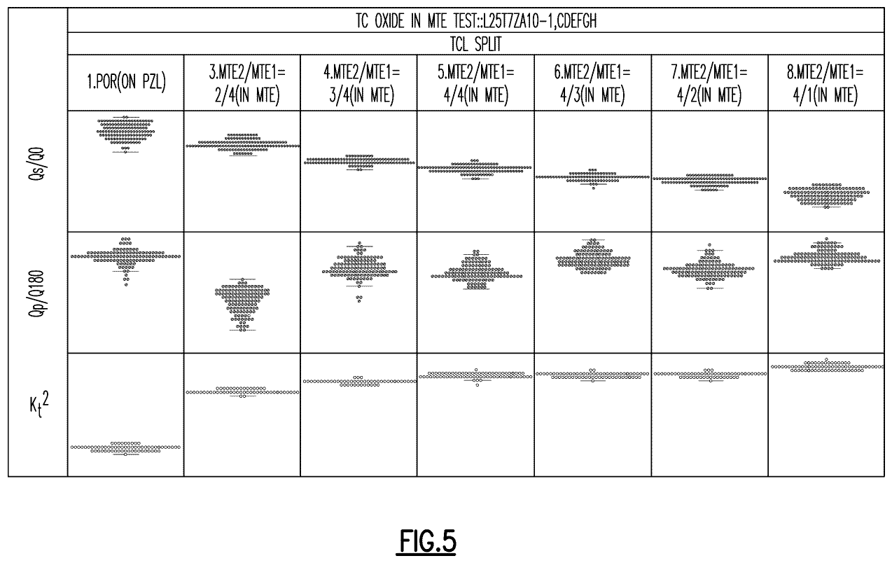

As discussed previously, in different embodiments the layer of TC material disposed within an electrode of a BAW resonator may be either continuous (see FIG. 3A) or patterned (see FIG. 3B). In some embodiments, the TC material may be patterned as a series of strips, optionally as a plurality of parallel strips disposed across the active area of the resonator, for example, as shown in FIG. 7. The plurality of parallel strips may be coplanar as illustrated. In other embodiments, the TC material may be provided as a plurality of rectangles, squares, ovals or circles, or a mesh or grid pattern instead of as strips. The cross-sections in FIG. 3B or on the right of FIG. 3C may represent any of these TC material patterns.

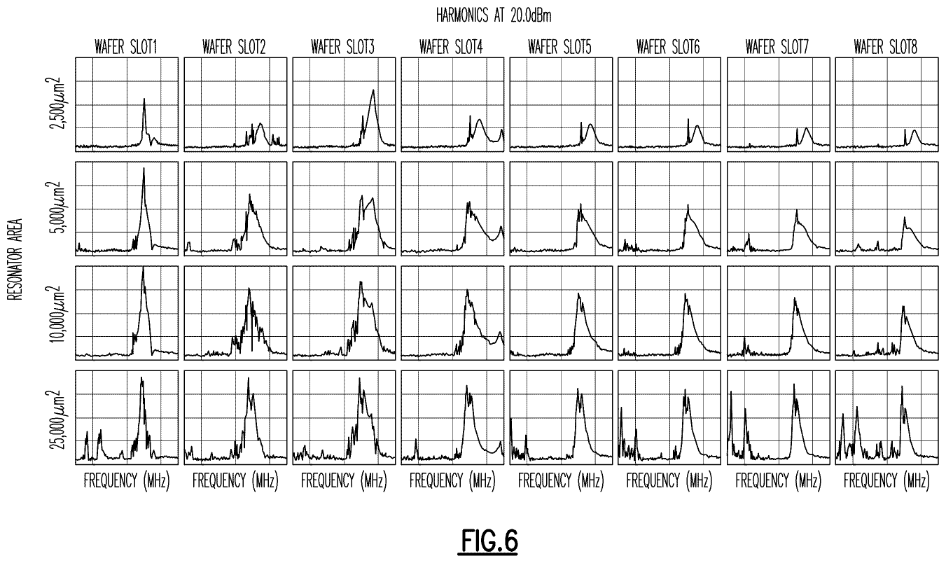

It was observed that in BAW resonators with the TC material disposed within an electrode of a BAW resonator as a series of strips, the duty factor of the TC material strips affected the resonance frequency of the resonator. FIG. 8 illustrates plots of Q and real admittance for examples of BAW resonators with TC material (silicon dioxide) disposed within the upper electrode of an example of a BAW resonator as a series of strips with different duty factors DF, with DF being defined as the amount of space between TC material strips divided by total area, and with the resonator having the “( 4/4)” material stack illustrated in FIG. 4. As can be observed the peak in Q and admittance (corresponding with resonance frequency) increased with increase in duty factor of the TC material strips for the different resonators. This shows that the resonance frequency of a BAW resonator including TC material disposed within an electrode of a BAW resonator as a series of strips may be tuned by selecting the duty factor of the TC material strips.

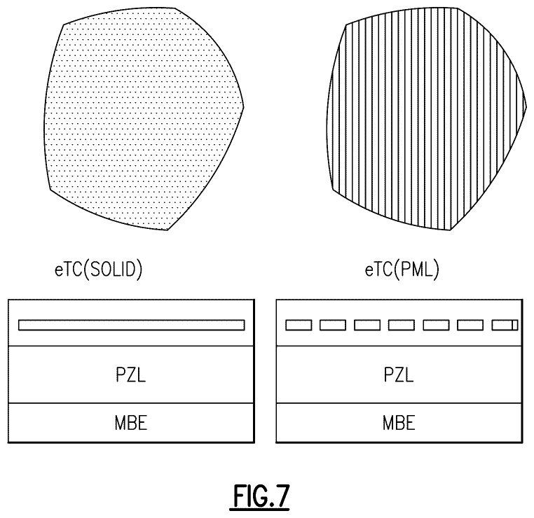

The acoustic wave devices discussed herein can be implemented in a variety of filters and packaged modules. Some example packaged modules will now be discussed in which any suitable principles and advantages of the packaged acoustic wave devices discussed herein can be implemented. FIGS. 9, 10, 11, and 12 are schematic block diagrams of an illustrative filter and packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example.

In some embodiments, multiple BAW resonators as disclosed herein may be combined into a filter, for example, an RF ladder filter schematically illustrated in FIG. 9 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

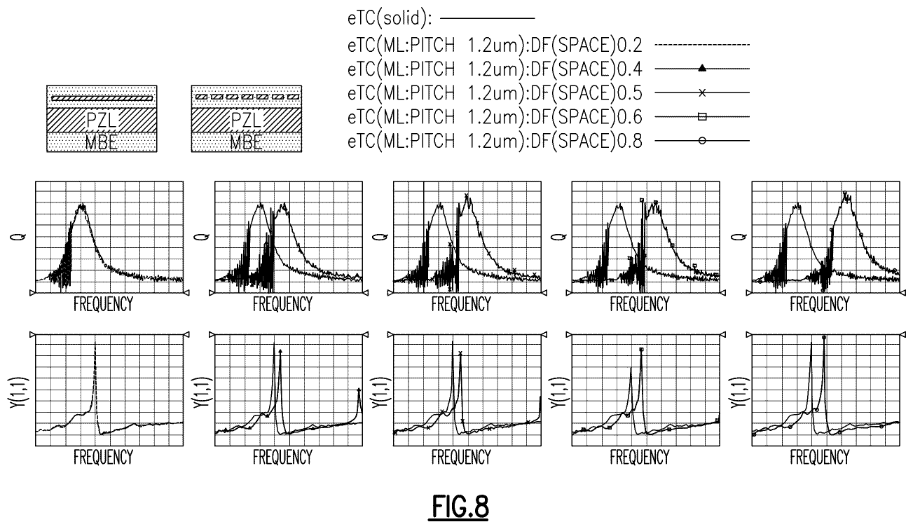

FIG. 10 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

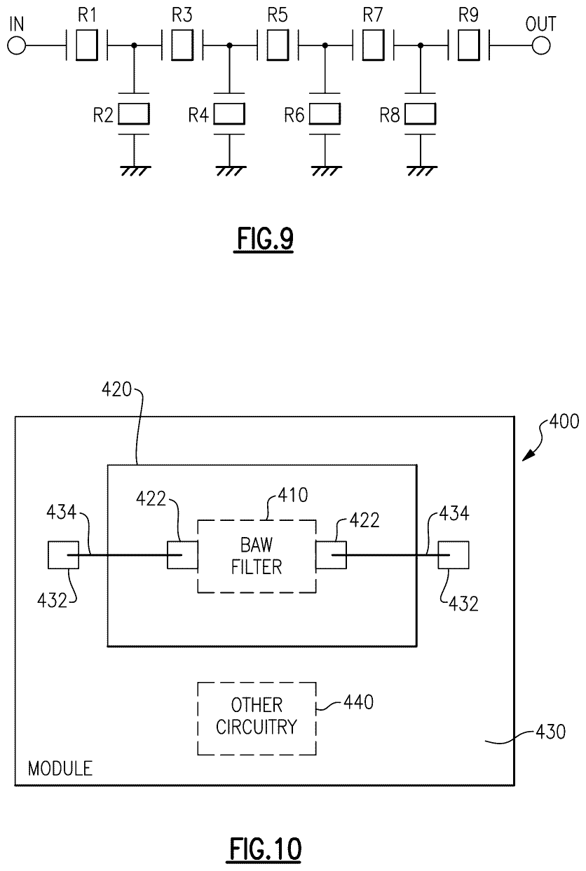

Referring to FIG. 11, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 11, however in other embodiments these components may be integrated into a common transceiver circuit or module. As will be appreciated by those skilled in the art, the front-end module 500 may include other components that are not illustrated in FIG. 11 including, but not limited to, switches, electromagnetic couplers, amplifiers, processors, and the like.

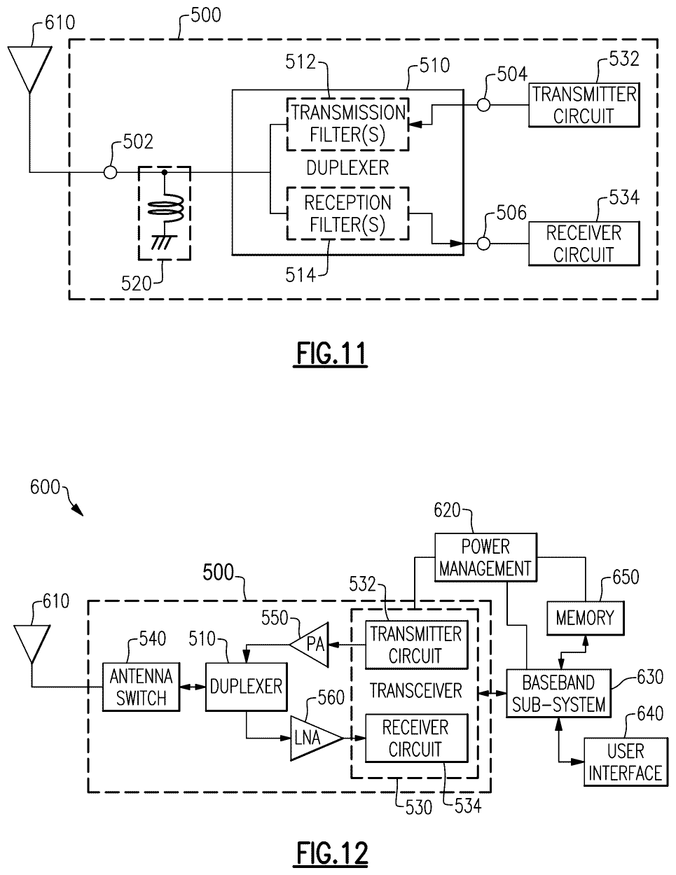

FIG. 12 is a block diagram of one example of a wireless device 600 including the antenna duplexer 510 shown in FIG. 11. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 11. The front-end module 500 includes the duplexer 510, as discussed above. In the example shown in FIG. 12 the front-end module 500 further includes an antenna switch 540, which can be configured to switch between different frequency bands or modes, such as transmit and receive modes, for example. In the example illustrated in FIG. 12, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 11.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 12, the front-end module 500 may further include a low noise amplifier module 560, which amplifies received signals from the antenna 610 and provides the amplified signals to the receiver circuit 534 of the transceiver 530.

The wireless device 600 of FIG. 12 further includes a power management sub-system 620 that is connected to the transceiver 530 and manages the power for the operation of the wireless device 600. The power management sub-system 620 can also control the operation of a baseband sub-system 630 and various other components of the wireless device 600. The power management sub-system 620 can include, or can be connected to, a battery (not shown) that supplies power for the various components of the wireless device 600. The power management sub-system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to. ” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A film bulk acoustic wave resonator comprising:
a layer of piezoelectric material disposed between a top electrode and a bottom electrode; and
a temperature compensating material disposed within one of the top electrode or the bottom electrode.

2. The film bulk acoustic wave resonator of claim 1 wherein the temperature compensating material has a positive temperature coefficient of frequency.

3. The film bulk acoustic wave resonator of claim 2 wherein the temperature compensating material includes one of silicon dioxide, doped silicon dioxide, or a metal having a positive temperature coefficient of frequency.

4. The film bulk acoustic wave resonator of claim 2 wherein the temperature compensating material is present in the one of the top electrode or the bottom electrode as an unpatterned layer of temperature compensating material.

5. The film bulk acoustic wave resonator of claim 4 wherein the layer of temperature compensating material is disposed within the top electrode and divides the top electrode into an upper portion and a lower portion.

6. The film bulk acoustic wave resonator of claim 5 wherein the upper portion is thicker than the lower portion.

7. The film bulk acoustic wave resonator of claim 6 wherein the lower portion is thicker than the layer of temperature compensating material.

8. The film bulk acoustic wave resonator of claim 5 wherein the upper portion is thinner than the lower portion.

9. The film bulk acoustic wave resonator of claim 4 wherein the temperature compensating material is disposed within the bottom electrode.

10. The film bulk acoustic wave resonator of claim 4 wherein the temperature compensating material is disposed within the top electrode and the bottom electrode.

11. The film bulk acoustic wave resonator of claim 2 wherein the temperature compensating material is present in the one of the top electrode or the bottom electrode as a patterned layer of material.

12. The film bulk acoustic wave resonator of claim 11 wherein the temperature compensating material is present in the one of the top electrode or the bottom electrode as a one of plurality of strips, a plurality of rectangles, a plurality of ovals, or as a grid of the temperature compensating material.

13. The film bulk acoustic wave resonator of claim 12 wherein the plurality of strips of temperature compensating material has a duty factor of at least 0.2.

14. The film bulk acoustic wave resonator of claim 12 wherein the plurality of strips of temperature compensating material has a duty factor of at least 0.5.

15. The film bulk acoustic wave resonator of claim 12 wherein the plurality of strips are coplanar.

16. The film bulk acoustic wave resonator of claim 15 wherein the temperature compensating material is disposed within at least one of the top electrode and the bottom electrode.

17. A radio frequency filter including the film bulk acoustic wave resonator of claim 1.

18. The radio frequency filter of claim 17 configured as a ladder filter.

19. A radio frequency module including the radio frequency filter of claim 17.

20. A radio frequency device including the radio frequency module of claim 19.
